(19) United States
(12) Patent Application Publication
(10) Pub. No.: US 2009/0042134 A1
(43) Pub. Date: Feb. 12, 2009

(54) Photosensitive composition, photosensitive planographic printing plate material, and image forming method of photosensitive planographic printing plate material

(75) Inventor: Toshiyuki Matsumura, Fujino-machi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Konica Minolta Medical & Graphic Inc., Tokyo (JP)

(21) Appl. No.: 12/232,349

(22) Filed: Sep. 16, 2008

Related U.S. Application Data
(63) Continuation-in-part of application No. 11/483,516, filed on Jul. 11, 2006.

(30) Foreign Application Priority Data
Jul. 14, 2005 (JP) JP2005-205663

(51) Int. Cl. G03F 7/027; G03F 7/20

(52) U.S. Cl. 430/286.1; 430/300

(57) ABSTRACT

A photosensitive composition containing: (A) a polymerizable compound containing an ethylenic double bond in the molecule; (B) a photopolymerization initiator; (C) a polymer binder; and (D) a dye exhibiting a maximum absorption wavelength of 350-450 nm, wherein the dye is represented by Formula (1):

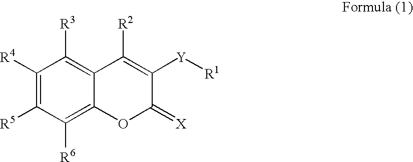

This is a continuation-in-part of application Ser. No. 11/483,586 filed on Jul. 11, 2006 with the U.S. Patent and Trademark Office.

This application is based on Japanese Patent Application No. 2005-205663 filed on Jul. 14, 2005 in Japan Patent Office, the entire content of which is hereby incorporated by reference.

### TECHNICAL FIELD

The present invention relates to a photosensitive planographic printing plate material employed in a computer-to-plate-system (hereinafter referred to as CTP), and particularly to a photosensitive planographic printing plate material which is suitable for exposure of a 350-450 nm wavelength laser beam, a photosensitive composition used for the same, and an image forming method using the same.

### BACKGROUND

In recent years, in printing plate production technologies for offset printing, developed and practiced has been CTP which directly records digital data, employing a laser beam, onto a photosensitive planographic printing plate.

Of these, in the printing field, in which a relatively long plate life is demanded, it has been known to employ negative-working photosensitive planographic printing plate materials having a polymerizable photosensitive layer incorporating polymerizable compounds (refer, for example, to Patent Documents 1 and 2).

Known as light sources employed for the polymerizable photosensitive layer are lasers such as an Ar laser (488 nm) and a YD-YAG (532 nm). However, in plate making employing such a light source, productivity of the plate-making process has not been sufficiently increased as desired due to insufficient output, and in the aspect of use of safelight, workability has also been insufficient.

On the other hand, in recent years, it has become possible to readily obtain downsized high-output lasers capable of continuously transmitting short wavelength light (350-450 nm wavelength).

Further, in order to improve the above productivity and safelight safety characteristics, developed are printing plate materials which are suitable for such short wavelength laser beams.

Known as such printing plate materials which are suitable for short wavelength laser beam are, for example, a printing plate material, described in Japanese Patent Publication for Public Inspection (hereinafter referred to as JP-A) No. 2000-98605, which has a photosensitive layer suitable for a 350-450 nm wavelength laser beam, which incorporates specified carbonyl compounds and titanocene compounds; a printing plate material, described in JP-A No. 2003-206307, which has a photosensitive layer suitable for a 450-550 laser beam, which incorporates specified sensitizing dyes and radical generating agents; a printing plate material, described in JP-A No. 2003-221517, which has a photosensitive layer suitable for a 350-450 nm wavelength laser beam, which incorporates specified styryl compounds; and a printing plate material (refer to Patent Documents 3 and 4) which incorporates, as a sensitizing dye, coumarin based compounds having a specified structure.

However, these printing plate materials tend to exhibit insufficient imaging speed. Consequently, it has been difficult to enhance the imaging speed while maintaining the desired plate life.

(Patent Document 1) JP-A No. 1-105238

(Patent Document 2) JP-A No. 2-127404

(Patent Document 3) JP-A No. 2002-214784

(Patent Document 4) JP-A No. 2003-21901

### SUMMARY

An object of the present invention is to provide a photosensitive planographic printing plate material which is suitable for exposure employing a 550-450 nm emission wavelength laser beam, and which exhibits desired imaging speed even stored at high temperature and excellent plate life, a photosensitive composition employed for the same, and an image forming method using the same. The object of the present invention can be achieved by a photosensitive composition comprising (A) a polymerizable ethylenic double bond-containing compound, (B) a photopolymerization initiator, (C) a polymer binder, and (D) a dye exhibiting a maximum absorption wavelength of 350-450 nm, wherein the dye is selected from coumarin derivatives.

### DESCRIPTION OF THE PREFERRED EMBODIMENTS

The above object of the present invention is enabled by employing the following embodiments.

(1) In a photosensitive composition comprising (A) polymerizable ethylenic double bond-containing compound, (B) photopolymerization initiator, (C) polymer binder, and (D) dye exhibiting a maximum absorption wavelength (λmax) of 350-450 nm, wherein the compound represented by following Formula (1) is incorporated as said (D) dye exhibiting a maximum absorption wavelength of 350-450 nm.

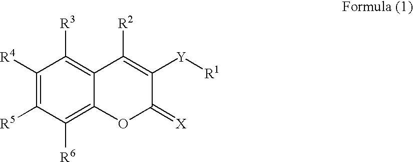

wherein R¹ represents an aryl group which may have a substituent, a heterocyclyl group which may have a substituent, or —CH═CH—R¹¹, where R¹¹ represents an alkenyl group which may have a substituent, or an aryl group which may have a substituent, R² and R³ each independently represents a hydrogen atom, a halogen atom, a cyano group, an alkyl group, an aryl group, or an acyl group, each of which may have a substituent; R⁴ and R⁶ each independently represents a hydrogen atom or an alkyl group which may have a substituent; R⁵ represents —NR⁷R⁸ or —OR⁹ where R⁷ and R⁸ each independently represents a hydrogen atom, an alkyl group, or an aryl group, each of which may have a substituent; and R⁷ and R⁴, and R⁸ and R⁶ may be joined to form a 5- to 6-membered ring; R⁹ represents an alkyl group or an aryl group, each of which may have a substituent; X represents an oxygen atom or a sulfur atom; and Y represents —CR¹⁰R¹¹, where R¹⁰ and R¹¹ each independently represents a hydrogen atom or an alkyl group.

(2) The photosensitive composition described in the above-described item 1 wherein R⁵ of the compound represented by above Formula (1) is above —NR⁷R⁸.
(3) The photosensitive composition described in the above-described items 1 or 2 wherein an iron arene complex compound is incorporated as (B) a photopolymerization initiator.
(4) The photosensitive composition described in the above-described items 1 or 2 wherein a biimidazole compound is incorporated as (B) a photopolymerization initiator.
(5) A photosensitive planographic printing plate material comprising a support having thereon a photosensitive layer composed of the photosensitive composition described in any one of the above-described items 1-4.
(6) An image forming method of a photosensitive planographic printing plate material wherein image exposure is performed onto the photosensitive planographic printing plate material described in the above-described item 5 via a 350-450 nm emission wavelength laser beam.

Based on the above embodiments of the present invention, it is possible to provide a photosensitive planographic printing plate material which is suitable for exposure via a 350-450 nm emission wavelength laser beam, a photosensitive composition employed for the same, and an image forming method employing the same.

The present invention is characterized in that in a photosensitive composition comprising (A) a polymerizable ethylenic double bond-containing compound, (B) a photopolymerization initiator, (C) a polymer binder, and (D) a dye exhibiting a maximum absorption wavelength of 350-450 nm, above (D) dye, exhibiting a maximum absorption wavelength of 350-450 nm, is the compound represented by above Formula (1).

In the present invention, in the photosensitive planographic printing plate material incorporating a support having thereon a photosensitive layer, it is possible to provide a photosensitive planographic printing plate material which exhibits higher imaging speed and excellent plate life by incorporating the compound represented by above Formula (1) in the above photosensitive layer.

### (Dyes of Maximum Absorption Wavelength of 350-450 nm)

The photosensitive composition of the present invention incorporates the compounds represented by above Formula (1) as (D) a dye exhibiting a maximum absorption wavelength of 350-450 nm.

In above Formula (1), R¹ represents an aryl group (for example, a phenyl group or a naphthyl group) or a heterocyclyl group (for example, a pyrrolidyl group, an imidazolydyl group, a morpholyl group, an oxazolydyl group, a thienyl group, a furyl group, a pyranyl group, a pyrazolyl group, a pyridyl group, a pyrazinyl group, or a pyrimidinyl group) which may have a substituent, or —CH═CH—R¹¹.

R¹¹ represents an alkenyl group, an aryl group (for example, a phenyl group or a naphthyl group), which may have a substituent, or a heterocyclyl group (for example, a pyrrolidyl group, an imidazolydyl group, a morpholyl group, an oxazolydyl group, a thienyl group, a furyl group, a pyranyl group, a pyrazolyl group, a pyridyl group, a pyrazinyl group, or a pyrimidinyl group), which may have a substituent.

R² and R³ each independently represents a hydrogen atom, a halogen atom, a cyano group, an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, or a pentadecyl group), which may have a substituent; an aryl group (for example, a phenyl group or a naphthyl group), which may have a substituent; or an acyl group (for example, an acetyl group, an ethylcarbonyl group, a propylcarbonyl group, a pentylcarbonyl group, a cyclohexyl carbonyl group, an octylcarbonyl group, a 2-ethylhexylcarbonyl group, a dodecylcarbonyl group, a phenylcarbonyl group, a naphthylcarbonyl group, or a pyridylcarbonyl group, which may have a substituent.

R⁴ and R⁶ each independently represents a hydrogen atom or an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, or a pentadecyl group), which may have a substituent.

R⁵ represents —NR⁷R⁸ or —OR⁹. R⁷ and R⁸ each independently represents a hydrogen atom, an alkyl group which may have a substituent, or an aryl group which may have a substituent.

Further, each pair of R⁷ and R⁴, and R⁸ and R⁶ may be joined to form a 5- to 6-membered ring. R⁹ represents an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, or a pentadecyl group), which may have a substituent, or an aryl group (for example, a phenyl group or a naphthyl group), which may have a substituent.

X represents an oxygen atom or a sulfur atom.

Y represents —CR¹⁰R¹¹, R¹⁰ and R¹¹ each independently representing a hydrogen atom or an alkyl group (for example, a methyl group or an ethyl group).

Of the compounds represented by Formula (1), in view of imagining speed, preferred are those in which R⁵ is —NR⁷R⁸.

Further, of the above compounds, particularly preferred are those in which X is O, and R² is a hydrogen atom, a methyl group, a trihalomethyl group, or a halogen atom.

The compounds represented by Formula (1) or (2) are listed below, however they are not limited thereto.

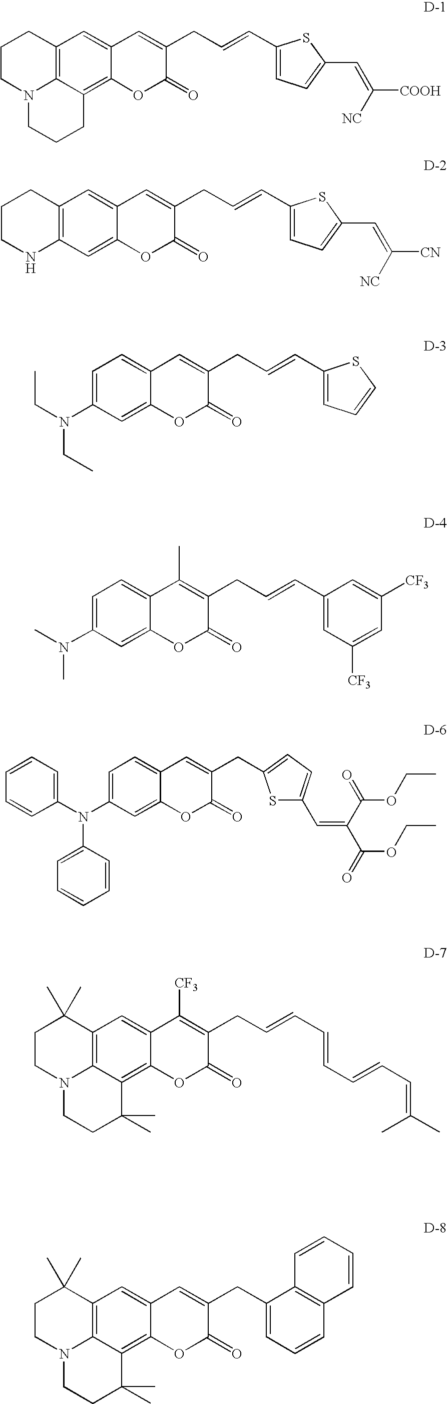

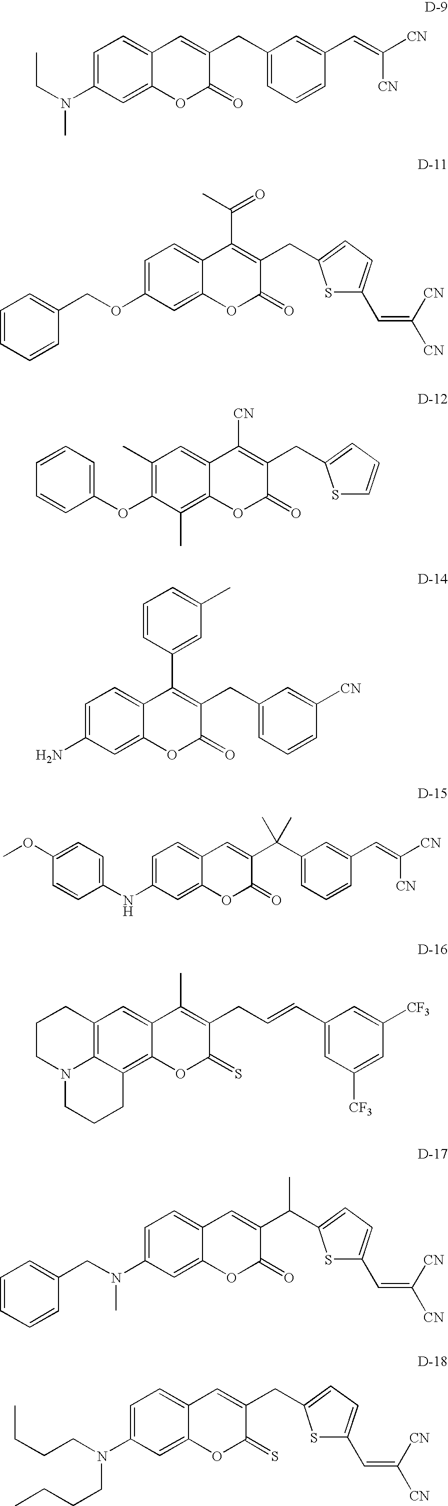

The content of the compounds represented by Formula (1) is preferably 50-300% by weight with respect to the photopolymerization initiators, but is more preferably 70-250% by weight.

Other than the above compounds, dyes of a maximum absorption wavelength of 350-450 nm include sensitizing dyes described, for example, in JP-A Nos. 2000-98605, 2000-147763, 2000-206690, 2000-258910, 2000-309724, 2001-042524, 2002-202598, and 2000-221790. Further, coumarin derivatives, other than those described in Formula (1), may be incorporated.

### (Polymerizable Ethylenic Double Bond-Containing Compounds)

(A) a polymerizable ethylenic double bond-containing compound according to the present invention is an polymerizable compound containing an ethylenic double bond.

Employed as polymerizable ethylenic double bond-containing compounds may be common radically polymerizable monomers, as well as multifunctional monomers or multifunctional oligomers, having a plurality of polymerizable ethylenic double bonds in the molecule, commonly employed as an ultraviolet radiation curing resin. Such compounds are not limited, and cited as preferred examples may be mono-functional acrylic acid esters of acrylate or of ε-caprolactone adducts of 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryloxyethyl acrylate, tetrahydrofurfuryloxyhexanolid acrylate or 1,3-dioxolane acrylate; monofunctional acrylic acid esters such as acrylates of ε-caprolactone adducts of 1,3-dioxane alcohol or 1,3-dioxolane acrylates, or methacrylic acid, itaconic acid, crotonic acid, maleic acid esters in which these acrylates are changed to methacrylate, crotonate, or maleate, such as ethylene glycol diacrylate, triethylene glycol diacrylate, pentaerythritol diacrylate, hydroquinone diacrylate, resorcinol diacrylate, hexanediol diacrylate, neopentylglycol diacrylate, tripropylene glycol diacrylate, diacrylate of hydroxypivalic acid neopentylglycol, diacrylate of neopentylglycol adipate, diacrylate of ε-caprolactone adduct of hydroxypivalic acid neopentyl glycol, ε-caprolactone adducts of 2-(2-hydroxy-1,1-dimethylethyl)-5-hydrocymethyl-5-ethyl-1,3-dioxane diacrylate, tricyclodecanedimethylol acrylate, or tricyclodecanedimethylol acrylate, bifunctional acrylic esters such as diacrylates of diglycidyl ether of 1,6-hexanediol, or methacrylic acid, itaconic acid, crotonic acid, and maleic acid esters, in which each of these acrylates are replaced with methacrylate, itaconate, crotonate, or maleate, such as ε-caprolactone adducts of trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexaacrylate, or dipentaerythritol hexaacrylate; multifunctional acrylic acid ester acids such as pyrogallol triacrylate, propionic acid-dipentaerythritol triacrylate, propionic acid-dipentaerythritol tetraacrylate, or hydroxypivalylaldehyde modified dimethylolpropane triacrylate or methacrylic acid, itaconic acid, crotonic acid, or maleic esters in which each of these acrylates is replaced with methacrylate, itaconate, crotonate, or maleate.

It is also possible to employ pre-polymers in the same manner as above. Listed as such pre-polymers may be the compounds described below. Further, it is possible to appropriately employ pre-polymers which are made to be photopolymerizable, and which are prepared in such a manner that acrylic acid or methacrylic acid is introduced into oligomers of an appropriate molecular weight. These pre-polymers may be employed individually or in combinations of at least two types, or via mixing with the above monomers and/or oligomers.

Examples of pre-polymers include polyester acrylates which are prepared in such a manner that (meth)acrylic acid is introduced into a polyester which is prepared by bonding polybasic acids such as adipic acid, trimellitic acid, maleic acid, phthalic acid, terephthalic acid, humic acid, malonic acid, succinic acid, glutaric acid, itaconic acid, pyromellitic acid, fumaric acid, pimelic acid, sebacic acid, dodecanic acid, or tetrahydrophthalic acid to polyhydric alcohol such as ethylene glycol, propylene glycol, diethylene glycol, propylene oxide, 1,4-butanediol, triethylene glycol, tetraethylene glycol, polyethylene glycol, glycerin, trimethylolpropane, pentaerythritol, sorbitol, 1,6-hexanediol, or 1,2,6-hexanetriol; epoxyacrylates which are prepared by introducing (meth)acrylic acid to epoxy resins such as bisphenol A-epichlorohydrin-(meth)acrylic acid, phenol novolak-epichlorohydrin-(meth)acrylic acid; urethane acrylates which are prepared by introducing (meth)acrylic acid to urethane resins such as ethylene glycol-adipic acid-tolylenediisocyanate-2-hydroxyethyl acrylate, polyethylene glycol-trorensiisocyanate-2-hydroxyethyl acrylate, hydroxyethylphthalyl methacrylate-xylene diisocyanate, 1,2-polybutadiene glycol-tolylenediisocyanate-2-hydroxyethyl acrylate, or trimethylolpropane-propylene glycol-tolylenediisocyanate-2-hydroxyethyl acrylate; silicone resin acrylates such as polysiloxane acrylate or polysiloxane-diisocyanate-2-hydroxyethyl acrylate; alkyd modified acrylates which are prepared by introducing a (meth)acryloyl group to oil-modified alkyd resins; and spirane resin acrylates.

The photosensitive layer according to the present invention is able to incorporate monomers such as phosphazene monomers, triethylene glycol, isocyanuric acid EO (ethylene oxide) modified diacrylate, isocyanuric acid EO modified triacrylate, dimethyloltricyclodecane diacrylate, trimethylolpropane acrylic acid benzoic acid ester, alkylene glycol type modified acrylic acid, or urethane modified acrylate, as well as addition-polymerizable oligomers and pre-polymers having constituting units formed of the above polymers.

Further listed as ethylenic double bond containing compounds capable of being simultaneously employed are phosphoric acid ester compounds having at least one (meth)acryloyl group. These compounds are those in which at least one of the hydroxyl groups of phosphoric acid undergoes esterification.

Cited as others may be the compounds described in JP-A Nos. 58-212994, 61-6649, 62-46688, 62-48589, 62-173295, 62-187092, 63-67189, and 1-244891. Further, in the present invention, appropriately employed may be the compounds described on pages 286-294 of “11290 no Kagaku Shohin (11290 Chemical Products)”, Kagakukogyo Nippo-sha, and on pages 11-65 of “UV•EB Handbook (Genryo Hen, (Raw Material Part)), Kobunshi Kankokai. Of these, compounds having at least two acryl or methacryl groups are preferred in the present invention, and further, preferred are those exhibiting a molecular weight of at most 10,000 but preferably at most 5,000.

Further, it is preferable to employ, in the photosensitive layer according to the present invention, polymerizable ethylenic double bond containing compounds having a tertiary amino group in the molecule. Though the structures are not particularly limited, preferably employed are those which are prepared by modifying tertiary amine compounds having a hydroxyl group employing glycidyl methacrylate, methacrylic acid chloride, or acrylic acid chloride. Specifically preferably employed are the polymerizable compounds described in JP-A Nos. 1-165613, 1-203413, and 1-197213.

Further in the present invention, it is preferable to employ the reaction products of polyhydric alcohols having a tertiary amino group in the molecule, being tertiary amine monomers, diisocyanate compounds, and compounds having a hydroxyl group as well as an addition-polymerizable ethylenic double bond in the molecule.

Polyhydric alcohols having a tertiary amino group in the molecule, as described herein, include, but are not limited to, triethanolamine, N-methyldiethanolamine, N-ethyldiethanolamine, N-n-butyldiethanolamine, N-tert.-butyldiethanolamine, N,N-di(hydroxyethyl)aniline, N,N,N′,N′-tetra-2-hydroxypropylethylenediamine, p-tolyldiethanolamine, N,N,N′,N′-tetra-2-hydroxyethylethylenediamine, N,N-bis(2-hydroxypropyl)aniline, allyldiethanolamine, 3-(dimethylamino)-1,2-propanediol, 3-diethylamino-1,2-propanediol, N,N-di(n-propyl)amino-2,3-propanediol, N,N-di(iso-propyl)amino-2,3-propanediol, and 3-(N-methyl-N-benzylamino)-1,2-propanediol.

Diisocyanate compounds include, but are not limited to, butane-1,4-diisocyanate, hexane-1,6-diisocyanate, 2-methylpentane-1,5-diisocyanate, octane-1,8-diisocyanate, 1,3-diisocyanatomethyl-cyclohexane, 2,2,4-trimethylhexane-1,6-diisocyanate, isoholondiisocyante, 1,2-phenylene diisocyanate, 1,3-phenylene diisocyanate, 1,4-phenylene diisocyanate, trilene-2,4-diisocyanate, trilene-2,5-diisocyanate, trilene-2,6-diisocyanate, 1,3-di(isocyanatomethyl)benzene, and 1,3-bis(1-isocyanato-1-methylethyl)benzene.

Examples of compounds, having a hydroxyl group and an addition-polymerizable ethylenic double bond in the molecule, include 2-hydroxyethyl methacrylate, 2-hyroxyethyl acrylate, 4-hydroxybutyl acrylate, 2-hydroxypropylene-1,3-dimethacrylate, and 2-hydroxypropylemne-1-methacrylate-3-acrylate.

These reactions are common for diol compounds, diisocyanate compounds, or hydroxyl group containing acrylate compounds, and may be performed in the same manner as the method used to synthesize urethane acrylates.

Further listed below are specific examples of reaction products of polyhydric alcohols having a tertiary amine group in their structure, diisocyanate compounds, and compounds having a hydroxyl group and an addition-polymerizable ethylenic double bond in their structure.
M-1: reaction product of triethanolamine (1 mol), hexane-1,6-diisocyanate (3 mol), and 2-hydroxyethyl methacrylate (3 mol)
M-2: reaction product of triethanolamine (1 mol), isophoronediisocyanate (3 mol), and 2-hydroxyethyl acrylate (3 mol)
M-3: reaction product of N-n-butyldiethanolamine (1 mol), 1,3-bis(1-isocyanato-1-methyethylbenzene (2 mol), and 2-hydroxypropylene-1-metahcrylate-3-acrylate (2 mol)
M-4: reaction product of N-n-butylethanolamine (1 mol), 1,3-di(isocyanatomethyl)benzene (2 mol), and 2hydroxypropylene-1-methacrylate-3-acrylate (2 mol)
M-5: reaction product of N-methyldiethanolamine (1 mol), trilene-2,4-diisocyanate (2 mol), and 2-hydroxypropylene-1,3-dimethacrylate (2 mol)
M-6: N-n-butyldiethanolamine (1 mol), 1,3-bis(1-isoxyanato-1-methylethyl)benzene (2 mol), and 2-hyroxyethyl methacrylate (2 mol)

Other than the above, it is also possible to employ the acrylates or alkyl acrylates described in JP-A Nos. 1-105238 and 2-127404.

### (Photopolymerization Initiators)

(B) photopolymerization initiators according to the present invention are compounds capable of initiating polymerization of (A) polymerizable ethylenic unsaturated bond containing compound via image exposure, and examples which are preferably employed include biimidazole compounds, iron arene complex compounds, titanocene, polyhalogen compounds, and monoalkyltriaryl compounds. Of these, particularly preferred are biimidazole compounds and iron arene complex compounds.

### (Biimidazole Compounds)

The biimidazole compounds according to the present invention are biimidazole derivatives, and include the compounds described in JP-A No. 2003-295426.

In the present invention, preferably incorporated as such biimidazole compounds are hexaarylbiimidazole (HABI, a dimer of triarylimidazole) compounds.

The production process of HABIs is described in DE No. 1,470,154, while use of these in a photopolymerizable composition is described in EP Nos. 24,629, and 107,792, U.S. Pat. No. 4,410,629, EP No. 215,453, and DE No. 3,211,312.

Examples of preferable derivatives include 2,4,5,2′,4′,5′-hexaphenylbiimidazole, 2,2′-bis(2-chlorophenyl)-4,5,4′,5′-tetraphenylbiimidazole, 2,2′-bis(2-bromophenyl)-4,5,4′,5′-tetraphenylbiimidazole, 2,2′-bis(2,4-dichlorophenyl)-4,5,4′,5′-tetraphenylbiimidazole, 2,2′-bis(2-chlorophenyl)-4,5,4′,5′-tetrakis(3-methoxyphenyl)biimidazole, 2,2′-bis(2-chlorophenyl)-4,5,4′,5′-tetrakis(3,4,5-trimethoxyphenyl)-biimidazole, 2,5,2′,5′-tetrakis(2-chlorophenyl)-4,4′-bis(3,4-dimethoxyphenyl)biimidazole, 2,2′-bis(2,6-dichlorophenyl)-4,4,4′,5′-tetraphenylbiimidazole, 2,2′-bis(2-nitrophenol)-4,5,4′,5′-tetraphenylbiimidazole, 2,2′-di-o-tolyl-4,5,4′,5′-tetraphenylbiimidazole, 2,2′-bis(2-ethoxyphenyl)-4,5,4′,5′-tetraphenylbiimidazole, and 2,2-bis82,6-difluorophenyl)-4,5,41,51-tetraphenylbiimidzole.

The amount of HABI is typically in the range of 0.01-30% by weight with respect to the total weight of the non-volatile component of the photosensitive composition, but is preferably in the range of 0.5-20% by weight.

### <Iron Arene Complex Compounds>

The iron arene complex compounds according to the present invention are those represented by following Formula (a).

[A—Fe—B]⁺X⁻ Formula (a)

wherein A represents a substituted or unsubstituted cyclopentadienyl group or a cyclohexadienyl group, and B represents a compound having an aromatic ring, while X⁻ represents an anion.

Specific examples of compounds having an aromatic ring include benzene, toluene, xylene, cumene, naphthalene, 1-methylnaphthalene, 2-methylnaphthalene, biphenyl, fluorene, anthracene, and pyrene, while specific examples of X⁻ include PF₆⁻, BF₄⁻, SbF₆⁻, AlF₄⁻, and CF₃SO₃⁻. Listed as substituents of a substituted cyclopentadienyl or cyclohexadienyl group are an alkyl group such as a methyl or ethyl group, a cyano group, an acetyl group, and a halogen atom.

The content ratio of the iron arene complex compounds is preferably 0.1-20% by weight with respect to the polymerizable group containing compounds, but is more preferably 0.1-10% by weight.

Listed below are specific examples of the above iron arene complex compounds.
Fe-1: (η6-benzene)(η5-cyclopentadienyl)iron(2) hexafluorophosphate
Fe-2: (η6-toluene)(η5-cyclopentadienyl)iron(2) hexafluorophosphate
Fe-3: (η6-cumene) (η5-cyclopentadienyl)iron(2) hexafluorophosphate
Fe-4: (η6-benzene)(η5-cyclopentadienyl)iron(2) hexafluoroarsenate
Fe-5: (η6-benzene)(η5-cyclopentadienyl)iron(2) tetrafluoroborate
Fe-6: (η6-naphthalene)(η5-cyclopentadienyl)iron(2) hexafluorophosphate
Fe-7: (η6-anthracene)(η5-cyclopentadienyl)iron(2) hexafluorophosphate
Fe-8: (η6-pyrene)(η5-cyclopentadienyl)iron(2) hexafluorophosphate
Fe-9: (η6-benzene)(η5-cyanocyclopentadienyl)iron(2) hexafluorophosphate
Fe-10: (η6-toluene)(η5-acetylcyclopentadienyl)iron(2) hexafluorophosphate
Fe-11: (η6-cumene)(η5-cyclopentadienyl)iron(2) tetrafluoroborate
Fe-12: (η6-pyrene)(ηn5-carboethoxycyclohexadienyl)iron(2) hexafluorophosphate
Fe-13: (η6-benzene)(η5-1,3-dichlorocyclohexadienyl)iron(2) hexafluorophosphate
Fe-14: (η6-pyrene)(η5-cyclohexadienyl)iron(2) hexafluorophosphate
Fe-15: (η6-acetophenone)(η5-cyclohexadienyl)iron(2) hexafluorophosphate
Fe-16: (η6-methyl benzoate)(η5-cyclopentadienyl)iron(2) hexafluorophosphate
Fe-17: (η6-benzenesulfoamido)(η5-cyclopentadienyl)iron(2) terafluoroborate
Fe-18: (η6-benzamido)(η5-cyclopentadienyl)iron(2) hexafluorophosphate
Fe-19: (η6-cyanobenzene)(η5-cyanocyclopentadienyl)iron(2) hexafluorophosphate
Fe-20: (η6-chloronaphthalene)(η5-cyclopentadienyl)iron(2) hexafluorophosphate
Fe-21: (η6-anthracene)(η5-cyanocyclopentadienyl)iron(2) hexafluorophosphate
Fe-22: (η6-chlorobenzene)(η5-cyclopentadienyl)iron(2) Hexafluorophosphate and
Fe-23: (η6-chlorobenzene)(η5-cyclopentadienyl)iron(2) tetrafluoroborate

It is possible to synthesize these compounds based on the method described in Dokl. Akd. Nauk SSSR 149 615 (1963).

Titanocene compounds include those described in JP-A Nos. 63-41483 and 2-291. Further preferably specific examples include bis(cyclopentadienyl)-Ti-di-chloride, bis(cyclopentadienyl)-Ti-bis-phenyl, bis(cyclopentadienyl)-Ti-bis-2,3,4,5,6-pentafluorophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,6-difluorophenyl (being IRUGACURE 727L, produced by Ciba Specialty Chemicals Co.), bis(cyclopentadienyl)-bis(2,6-difluoro-3-pyri-1-yl)phenyl) titanium (being IRUGACURE 784, produced by Ciba Specialty Chemicals Co.), bis(cyclopentadienyl)-bis(2,4,6-trifluoro-3-(pyri-1-yl)phenyl) titanium, and bis(cyclopentadienyl)-bis(2,4,6-trifluoro-3-(2-5-dimthylpyri-1-yl)phenyl)titanium.

Listed as polyhalogen compounds are those which have a trihalogenmethyl group, a dihalogenmethyl group, or a halogenmethyl group.

Of these, preferably employed are polyhaloacetyl compounds bur more preferably employed are trihaloacetylamide compounds.

Listed as polyhaloacetyl compounds are those represented by following Formula (2) but preferably are those represented by following Formula (3).

R¹¹—C(X¹⁰)₂—(C═O)—R¹² Formula (2)

wherein X¹⁰ represents a chlorine atom or a bromine atom; R¹¹ represents a hydrogen atom, a chlorine atom, a bromine atom, an alkyl group, an aryl group, an acyl group, an alkylsulfonyl group, an arylsulfonyl group, or a cyano group; and R¹² represents a univalent substituent. R¹¹ and R¹² may be joined to form a ring.

C(X¹¹)₃—(C═O)—Y¹⁰—R¹³ Formula (3)

wherein X¹¹ represents a chlorine atom or a bromine atom; R¹³ represents a univalent substituent; and Y¹⁰ represents —O— or —NR¹⁴ where R¹⁴ represents a hydrogen atom or an alkyl group. R¹³ and R¹⁴ may be joined to form a ring.

Specific examples (BR1-BR76) of the compounds represented by above Formula (2) are listed below.

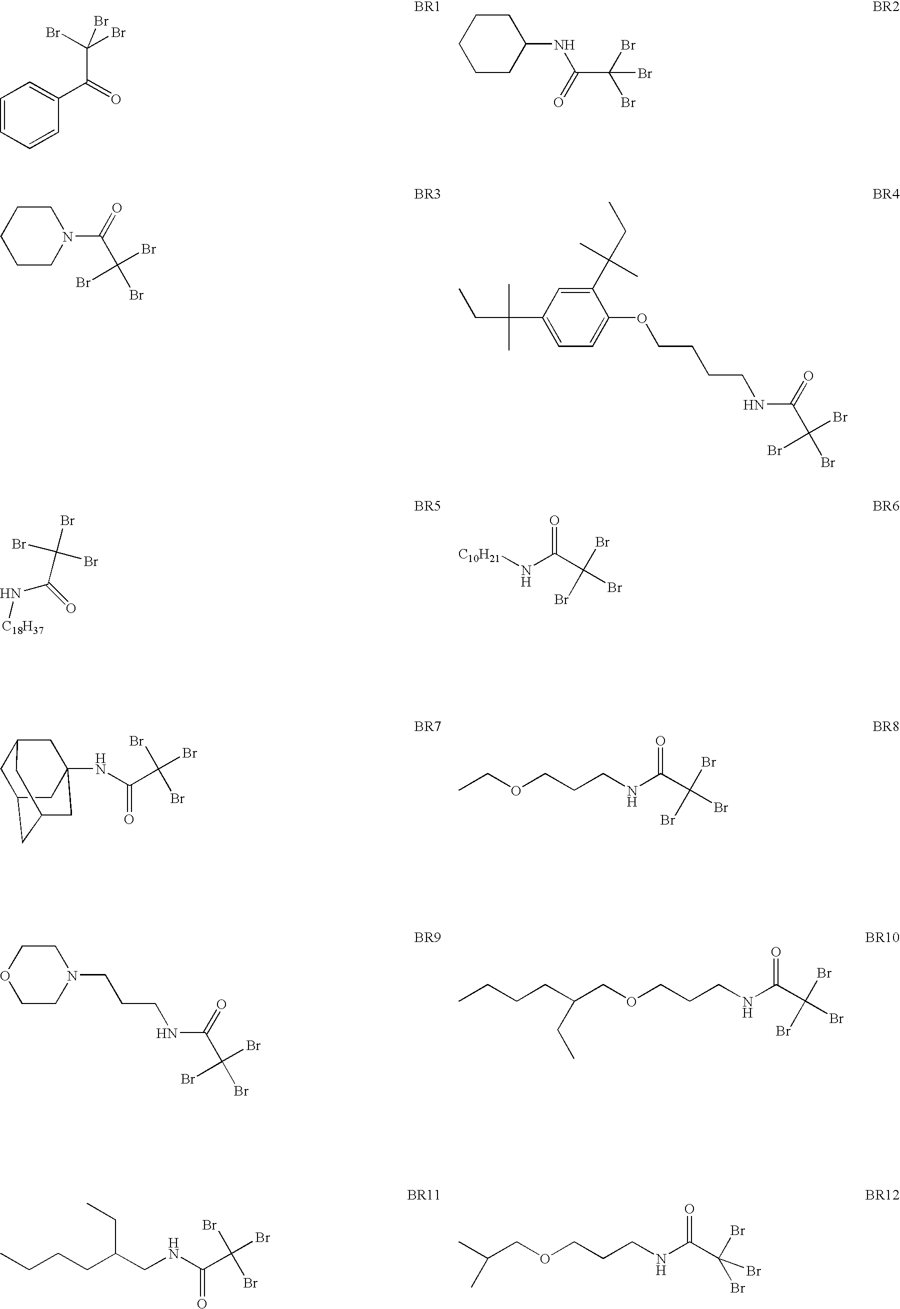

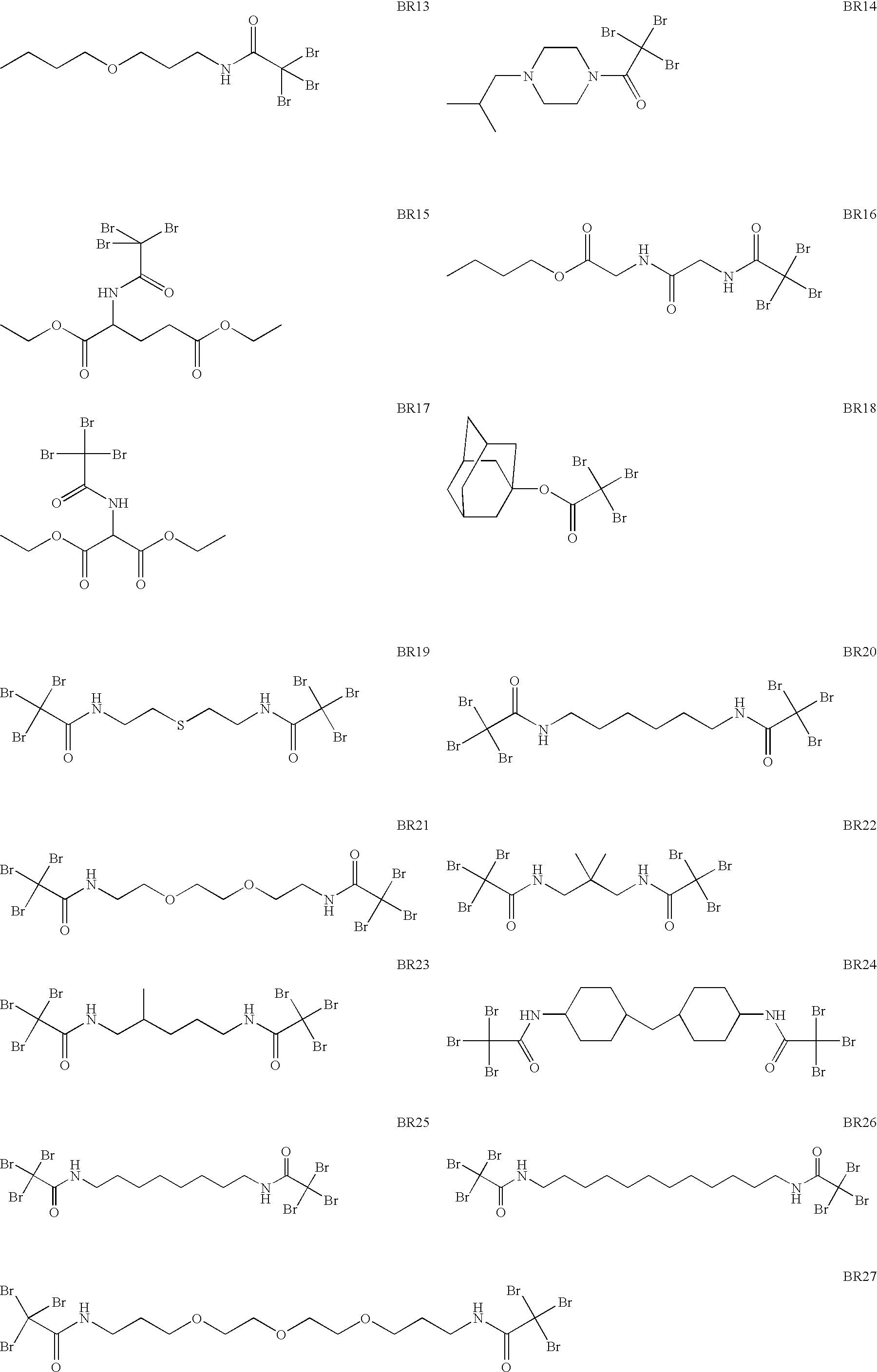

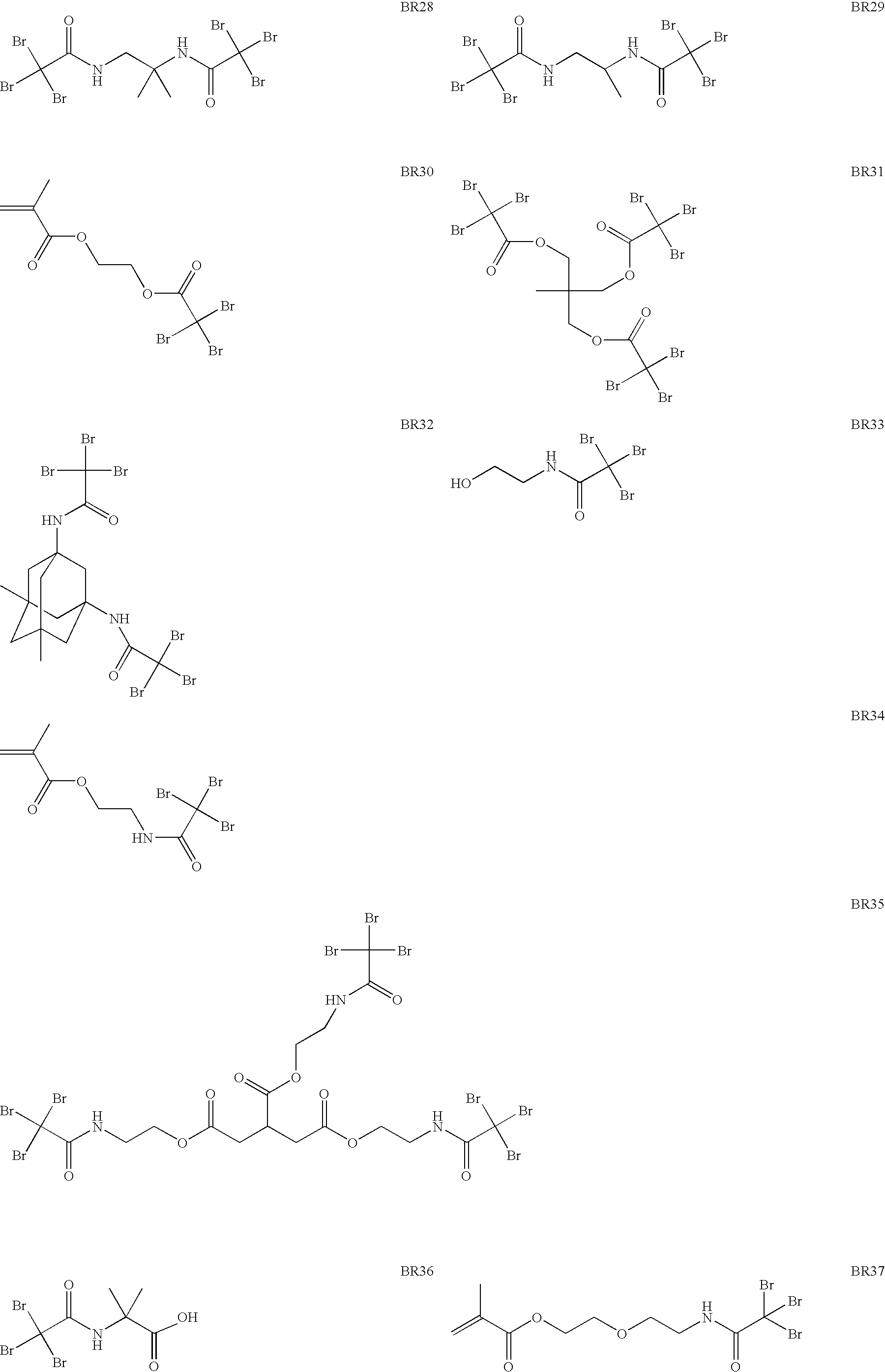

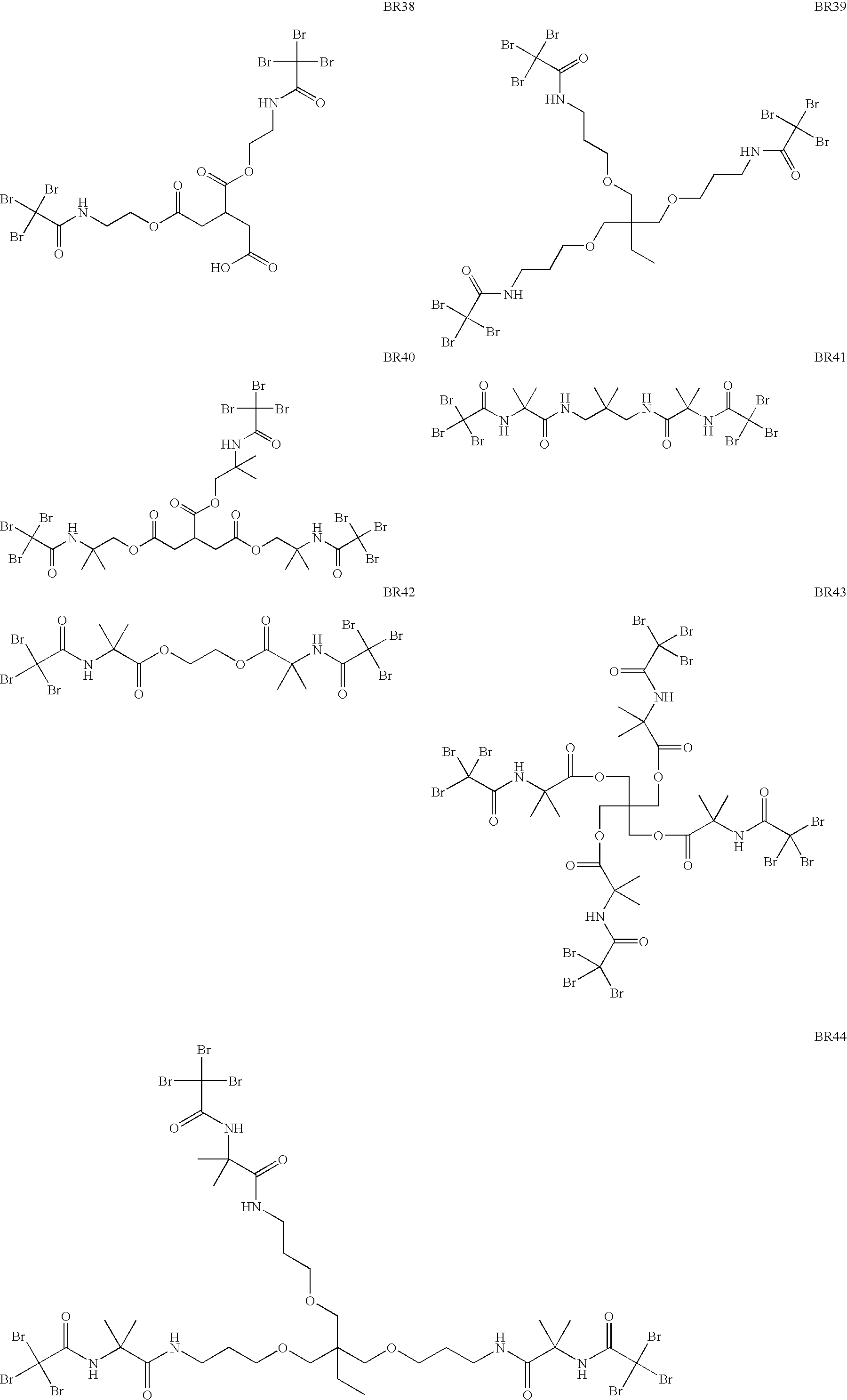

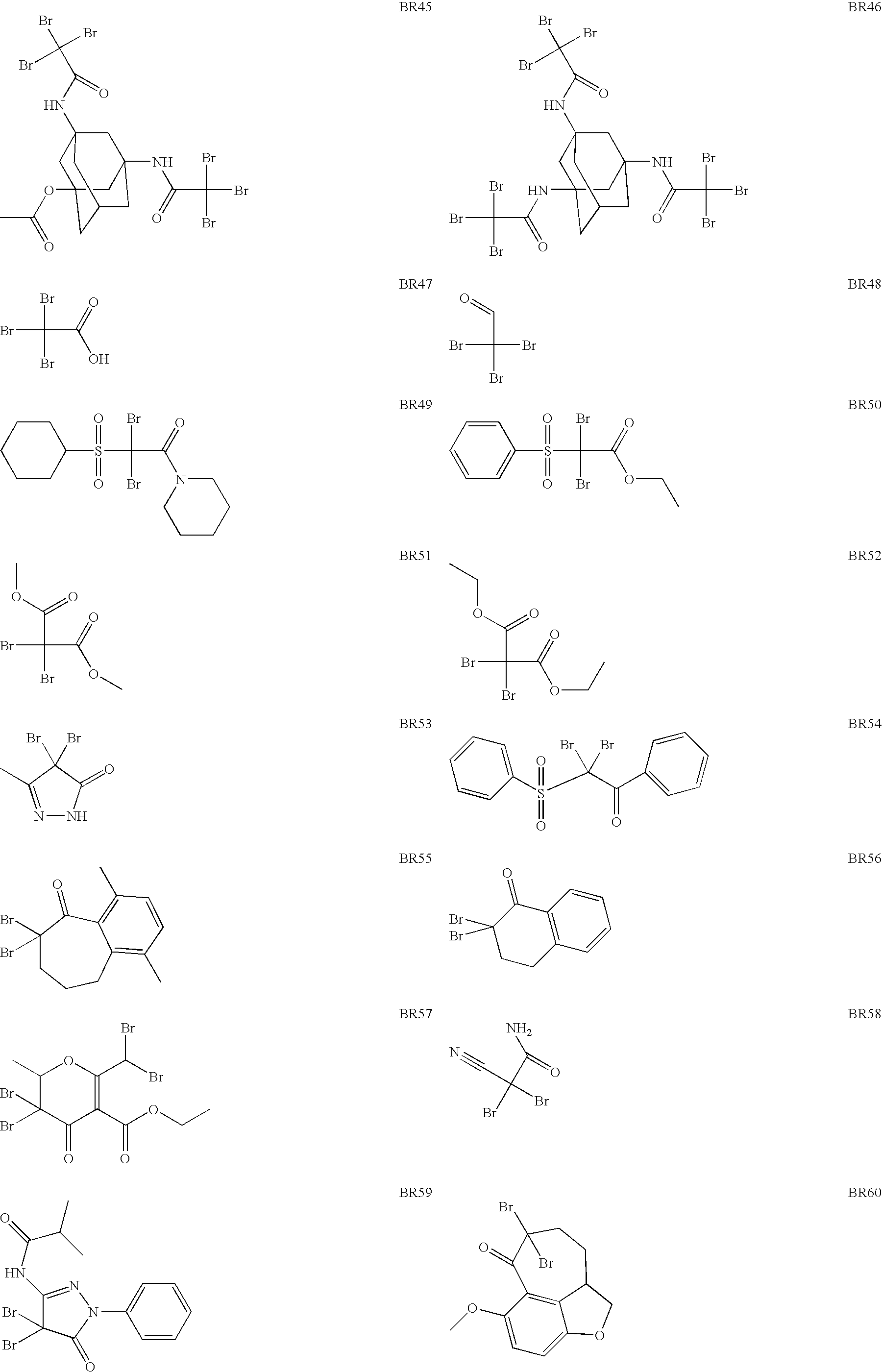

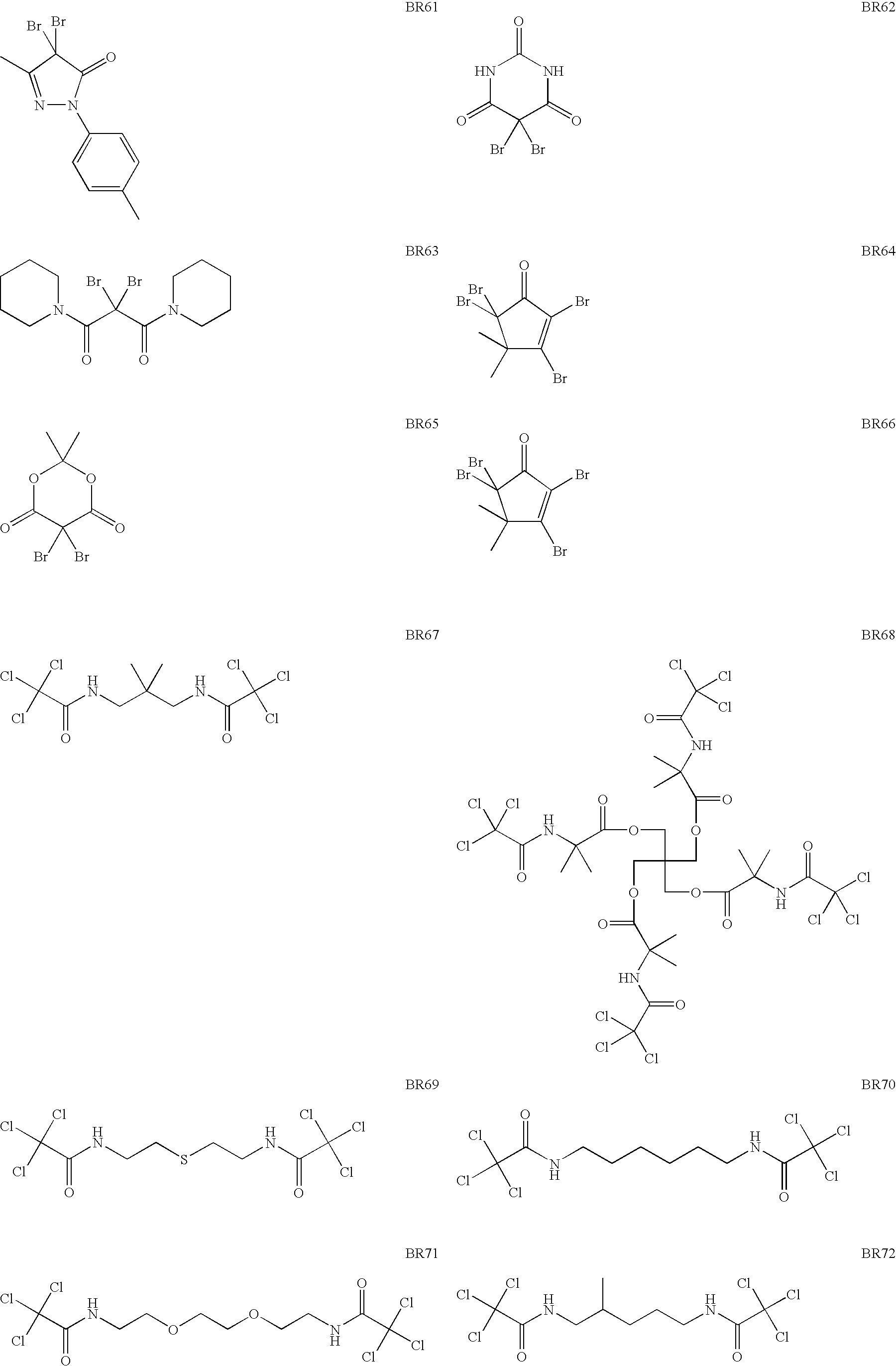

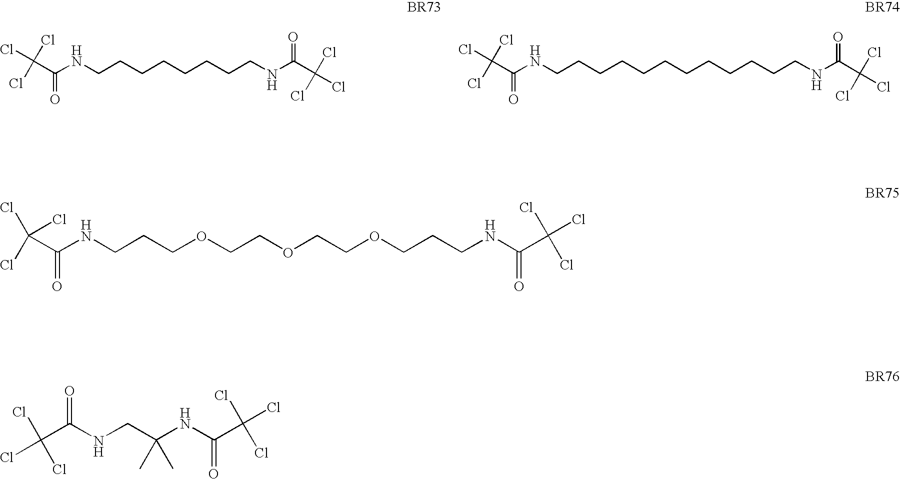

Listed as polyhalogen compounds usable in the present invention are the trihalomethyltriazine compounds described below.

Examples include the compounds described in Wakabayashi et al., Bull. Chem. Soc. Japan, 42, 2924 (1969) such as 2-phenyl-4,6-bis(trichloromethyl)-S-triazine, 2-(p-chlorophenyl)-4,6-bis(trichloromethyl)-S-triazine, 2-(p-tolyl)-4,6-bis(trimethyl)-S-triazine, 2-(p-methoxyphenyl)-4,6-bis(trichloromethyl-S-triazine, 2-(2′,4′-dichlorophenyl)-4,6-bis(trichloromethyl)-S-triazine, 2,4,6-tris(trichloromethyl)-S-triazine, 2-methyl-4,6-bis(trichloromethyl)-S-triazine, 2-n-nonyl-4,6-bis(trichloromethyl)-S-triazine, or 2-(α,α,β-trichloroethyl)-4,6-bis(trichloromethyl)-S-triazine. In addition to the above, listed may be the compounds, described in British Patent No. 1388492, such as 2-styryl-4,6-bis(trichloromethyl)-S-triazine, 2-(4-styrylphenyl)-4,6-bis(trichloromethyl)-S-triazine, 2-(p-methylstyryl)-4,6-bis(trichloromethyl)-S-triazine, 2-(p-methoxystyryl)-4,6-bis(trichloromethyl)-S-triazine, or 2-(p-methoxystyryl)-4-amino-6-trichloromethyl-S-triazine; the compounds, described in JP-A No. 53-133428, such as 2-(4-methoxy-naphtho-1-yl)-4,6-bis-trichloromethyl-S-triazine, 2-(4-ethoxy-naphtho-1-yl)-4,6-bis-trichloromethyl-S-triazine, 2-[4-(2-ethoxyethyl)-naphtho-1-yl]4,6-bis-trichloromethyl-S-triazine, or 2-(4,7-dimethoxy-naphtho-1-yl)-4,6-bis-trichloromethyl-S-triazine; and the compounds described in German Patent No. 3337024. Further listed may be the compounds, described in F. C. Schaefer et al., J. Org. Chem., 29, 1527 (1964), such as 2-methyl-4,6-bis(tribromomethyl)-S-triazine, 2,4,6-tris(tribromomethyl)-S-triazine, 2,4,6-tris(dibromomethyl)-S-triazine, 2-amino-4-methyl-6-trobromomethyl-S-triazine, or 2-methoxy-4-methyl-6-trochloromethyl-S-triazine.

Listed as monoalkyltriaryl borates are the compounds described in JP-A Nos. 62-150242 and 62-143044. Listed as more preferable specific examples are tetra-n-butylammonium-n-butyltrinaphthalene-1-yl-borate, tetra-n-butylammonium-n-butyltriphenyl-borate, tetra-n-butylammonium-n-butyl-tri-(4-tert-butylphenyl)-borate, tetra-n-butylammonium-n-hexyl-tri-(3-chloro-4-methylphenyl)-borate, and tetra-n-butylammonium-n-hexyl-tri-(3-fluorophenyl)-borate.

The added amount of photopolymerization initiators in the photosensitive layer is not particularly limited, but is preferably in the range of 0.1-20% by weight with respect to the photosensitive layer, but is most preferably in the range of 0.8-15% by weight.

### ((C) Polymer Binders)

Polymer binders will now be described.

Employed as the polymer binders according to the present invention may be acryl based polymers, polyvinyl butyral resins, polyurethane resins, polyamide resins, polyester resins, epoxy resins, phenol resins, polycarbonate resins, and polyvinyl formal resins, as well as shellac and other natural resins. These may be employed in combinations of at least two types.

Of these, preferred are vinyl based copolymers produced by copolymerizing acryl based monomers. Further, it is preferable that the polymer binders are copolymers composed of (a) carboxyl groups containing monomers, and (b) copolymers of alkyl methacrylates or alkyl acrylates.

Preferred specific examples of monomers having a carboxyl group include α, β-unsaturated carboxylic acids such as acrylic acid, methacrylic acid, maleic acid, maleic anhydride, itaconic acid, and itaconic anhydride. In addition, also preferred are carboxylic acids such as a halfester of phthalic acid and 2-hydroxymethacrylate.

Specific examples of alkyl methacrylates and alkyl acylates include unsubstituted alkyl esters such as methyl methacrylate, ethyl methacrylate, propyl methacrylate, butyl methacrylate, amyl methacrylate, hexyl methacrylate, heptyl methacrylate, octyl methacrylate, nonyl methacrylate, decyl methacrylate, undecyl methacrylate, dodecyl methacrylate, methyl acrylate, ethyl acrylate, propyl acrylate, butyl acrylate, amyl acrylate, hexyl acrylate, heptyl acrylate, octyl acrylate, nonyl acrylate, decyl acrylate, undecyl acrylate, or dodecyl acrylate; cyclic alkyl esters such as cyclohexyl methacrylate or cyclohexyl acrylate; as well as substituted alkyl esters such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate, or glycidyl acrylate.

Further, in the polymer binders of the present invention, employed as other copolymerization monomers may be those described in following (1)-(14).

1) Monomers having an aromatic hydroxyl group, such as o- (or p- or m-) hydroxystyrene or o- (or p- or m-) hydroxyphenyl acrylate
2) Monomers having an aliphatic hydroxyl group, such as 2-hydroxyethyl acrylate, 2-hydroxyethyl methacrylate, N-methylolacrylamide, 4-hydroxybutyl methacrylate, 5-hydroxypentyl acrylate, 5-hydroxypentyl methacrylate, 6-hydroxythexyl acrylate, 6-hydroxyhexyl methacrylate, N-(2-hydroxyethyl)acrylamide, N-(2-hydroxyethyl)methacrylamide, or hydroxyethyl vinyl ether
3) Monomers having an aminosulfonyl group, such as m- (or p-) aminosulfonylphenyl methacrylate, m- (or p-) aminosulfonylphenyl acrylate, N-(p-aminosulfonylphenyl)methacrylamide, or N-(p-aminosulfonylphenyl)acrylamide
4) Monomers having a sulfonamide group, such as (p-toluenesulfonyl)acrylamide or N-(p-toluenesulfonyl)methacrylamide
5) Acrylamides or methacrylamides, such as acrylamide, methacrylamide, N-ethylacrylamide, N-hexylacrylamide, N-cyclohexylacrylamide, N-phenylacrylamide, N-(4-nitrophenyl)acrylamide, N-ethyl-N-phenylacrylamide, N-(4-hyroxyphenyl)acrylamide, or N-(4-hydroxyphenyl)methacrylamide
6) Monomers having a fluorinated alkyl group, such as trifluoroethyl acrylate, trifluoroethyl methacrylate, tetrafluoropropyl methacrylate, hexafluoropropyl methacrylate, octafluoropentyl acrylate, octafluoropentyl methacrylate, heptadecafluorodecyl methacrylate, or N-butyl-N-(2-acryloxyethyl)heptadecafluorooctylsulfonamide
7) Vinyl ethers, such as ethyl vinyl ether, 2-chloroethyl vinyl ether, propyl vinyl ether, butyl vinyl ether, octyl vinyl ether, or phenyl vinyl ether
8) Vinyl esters, such as vinyl acetate, vinyl chloroacetate, vinyl butyrate, or vinyl benzoate
9) Styrenes such as styrene, methylstyrene, or chloromethylstyrene
10) Vinyl ketones, such as methyl vinyl ketone, ethyl vinyl ketone, propyl vinyl ketone, or phenyl vinyl ketone
11) Olefins, such as ethylene, propylene, i-butylene, or isoprene
12) N-vinylpyrrolidone, N-vinylcarbazole, or 4-vinylpyridine
13) Monomers having a cyano group, such as acrylonitrile, methacrylonitrile, 2-pentenenitrile, 2-methyl-3-butenenitrile, 2-cyanoethyl acrylate, or o-) or m- or p-) cyanostyrene, and
14) Monomers having an amino group, such as N,N-diethylaminoethyl methacrylate, N,N-dimethylaminoethyl acrylate, N,N-dimethylaminoethyl methacrylate, polybutadieneurethane acrylate, N,N-dimethylaminopropylacrylamide, N,N-dimethylaminopropylacrylamide, N,N-dimethylacrylamide, acryloylmorpholine, N-i-propylacrylamide, or N,N-diethylacrylamide.

Further, other monomers capable of copolymerizing with these monomers may be copolymerized.

Further, the polymer binders of the present invention are preferably vinyl based polymers having a carboxyl group on the side chain and a polymerizable double bond. It is possible to produce such binders in such a manner that a carboxyl group in the molecule of the above vinyl based copolymers undergoes addition reaction with compounds having, in the molecule, a (meth)acryloyl group and an epoxy group. Unsaturated bond containing vinyl based copolymers are also preferred as a polymer binder.

Specific examples of compounds having, in the molecule, both an unsaturated bond and an epoxy group include glycidyl acrylate and glycidyl methacrylate, as well as epoxy group containing unsaturated compounds described in JP-A No. 11-271969. Further, it is possible to produce the above compounds in such a manner that the hydroxyl group in the molecule of the above vinyl based polymers undergoes addition reaction with compounds having, in the molecule, a (meth)acryloyl group and an isocyanate group. Unsaturated bond containing vinyl based copolymers are also preferred as a polymer binder. Preferably listed as compounds having, in the molecule, both an unsaturated bond and an isocyanate group are vinyl isocyanate, (meth)acryl isocyanate, 2-(meth)acryloyloxyethyl isocyanate, and m- or p-isopropenyl-α,α′-dimethylbenzyl isocyanate, while listed are (meth)acryl isocyanate and 2-(meth)acryloyloxyethyl isocyanate.

The content of the above vinyl based polymers having a carboxyl group on the side chain and a polymerizable double bond employed in the present invention is preferably 50-100% by weight with respect to all the polymer binders, but is more preferably 100 by weight.

The content of the polymer binders in the photosensitive layer is preferably in the range of 10-90% by weight, is more preferably 15-70% by weight, but is most preferably 20-50% by weight in view of the imaging speed.

### (Various Additives)

Other than the above components, in order to inhibit excessive polymerization of polymerizable ethylenic double bond monomers during production, or storage, of photosensitive planographic printing plates, it is preferable to incorporate polymerization inhibitors in the photosensitive compositions of the present invention.

Listed as such appropriate polymerization inhibitors are hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), N-nitrosophenylhydroxylamine Ce(III) salts, and 2-t-butyl-6-(3-t-butyl-2-hydroxy-5-methylbenzyl)-4-methylphenyl acrylate.

The added amount of the polymerization inhibitors is preferably about 0.01—about 5% by weight with respect to the total solid weight of the above composition. Further, if desired, in order to minimize polymerization inhibition due to oxygen, behenic acid or higher fatty acid derivatives such as behenic acid amide may be incorporated or localized on the surface of the photosensitive layer during the drying process. The added amount of the higher fatty acid derivatives is preferably about 0.5—about 10% with respect to the total composition.

Further, it is possible to employ colorants. Appropriately employed as such colorants may be those known in the art, including commercial products. Examples include those described in “Ganryo Binran (Pigment Handbook)”, Revised New Edition, Edited by Nihon Ganryo Gijutsu Kyokai (Seibundo Shinkosha), and the Color Index Handbook.

Listed as types of pigments are black pigments, yellow pigments, red pigments, brown pigments, violet pigments, blue pigments, green pigments, fluorescent pigments, and metal powder pigments. Specific examples include inorganic pigments (titanium dioxide, carbon black, graphite, zinc oxide, Prussian blue, cadmium sulfide, and iron sulfide, as well as chromates of lead, zinc, barium, or calcium), in addition to organic pigments (such as azo based, thioindigo based, anthraquinone based, anthoanthrone based, or triphenedioxazine based pigments, vat dye pigments, phthalocyanine pigments and derivatives thereof, and quinacridone pigments).

Of these, preferably employed are pigments which exhibit substantially no absorption in the absorption wavelength region of the spectral sensitizing dyes corresponding to the employed exposure laser beam. In such a case, the reflection absorption of pigments, which is determined employing an integrating sphere in the wavelength of the used laser beam, is at most 0.05. Further, the added amount of pigments is preferably 0.1-10 by weight with respect to the solids of the above compositions, but is more preferably 0.2-5% by weight.

In view of pigment absorption in the above photosensitive wavelength region and image visibility after development, it is preferable to employ violet pigments and blue pigments. Listed as such pigments may, for example, be cobalt blue, cerulean blue, alkali blue lake, phonatone blue 6G, Victoria blue lake, metal-free phthalocyanine blue, phthalocyanine blue, fast sky blue, indanthrene blue, indigo, dioxane violet, isoviotanthrone violet, indanthrone blue, and indanthrone BC. Of these, more preferred are phthalocyanine blue and dioxane violet.

Further, the above composition is capable of incorporating surface active agents as a coatability enhancing agent in a range in which the performance of the present invention is not adversely affected. Of these, most preferred are fluorine based surface active agents.

Further, in order to improve physical properties of the hardened layer, incorporated may be additives such as inorganic fillers and plasticizers such as dioctyl phthalate, dimethyl phthalate, or tricresyl phosphate. The added amount of these is preferably at most 10% by weight with respect to the total solids.

Still further, preferably listed as solvents employed in the photosensitive layer liquid coating composition, which is prepared to provide the photosensitive layer according to the present invention, are, for example, alcohols including polyhydric alcohol derivatives such as sec-butanol, isobutanol, n-hexanol, benzyl alcohol, diethylene glycol, triethylene glycol, tetraethylene glycol, or 1,5-pentanediol; ethers such as propylene glycol monobutyl ether, dipropylene glycol monomethyl ether, or tripropylene glycol monomethyl ether; ketones; and esters such as ethyl lactate, butyl lactate, diethyl oxalate, or methyl benzoate.

In the foregoing, described is the photosensitive layer liquid coating composition. The photosensitive layer according to the present invention is constituted by applying the above composition onto a support.

The coated weight of the photosensitive layer according to the present invention is preferably 0.1-10 g/m², but is most preferably 0.5-5 g/m².

### (Protective Layer (Oxygen Shielding Layer))

If desired, it is possible to provide a protective layer on the top of the photosensitive layer according to the present invention.

It is preferable that the above protective layer (being an oxygen shielding layer) exhibits high solubility in the developer (commonly being an aqueous alkali solution) described below. Listed as specific examples of components are polyvinyl alcohol and polyvinylpyrrolidone. Polyvinyl alcohol retards penetration of oxygen, while polyvinyl ensures contact to the photosensitive layer.

If desired, employed together with the above two polymers are water-soluble polymers such as polysaccharide, polyethylene glycol, gelatin, glue, casein, hydroxyethyl cellulose, carboxymethyl cellulose, methyl cellulose, hydroxyethyl starch, gum Arabic, sucrose octaacetate, ammonium alginate, sodium alginate, polyvinylamine, polyethylene oxide, polystyrenesulfonic acid, polyacrylic acid, or water-soluble polyamide.

When a protective layer is provided on the photosensitive planographic printing plate material of the present invention, peel force between the photosensitive layer and the protective layer is preferably at least 35 mN/mm, is more preferably at least 50 mN/mm, but is still more preferably at least 75 mN/mm. Listed as preferred compositions of the protective layer are those described in Japanese Patent Application No. 8-161645.

It is possible to determine the peel force as described below. A width-specified adhesive tape, which exhibits sufficiently high adhesive force, is adhered onto the protective layer. Subsequently, determined is the required force to peel away the tape, together with the protective layer, at an angle of 90 degrees with respect to the plane of the photosensitive planographic printing plate material.

If desired, it is possible to incorporate, into the protective layer, surface active agents and matting agents. The protective layer is formed in such a manner that the above protective layer compositions are dissolved in appropriate solvents, after which the resulting solution is applied onto the photosensitive layer, followed by drying. It is particularly preferable that the main component of the coating solvents is water, or alcohols such as methanol, ethanol, or i-propanol.

When a protective layer is provided, its thickness is preferably 0.1-5.0 μm, but is most preferably 0.5-3.0 μm.

### (Supports)

The supports according to the present invention are thin plates or film capable of carrying a photosensitive layer, and preferably incorporate a hydrophilic surface on the photosensitive layer carrying side.

Listed as supports according to the present invention are, for example, metal plates composed of aluminum, stainless steel, chromium, or nickel, as well as those which are prepared by laminating a thin layer of any of the above metals or vacuum evaporating the same onto a plastic film such as polyester film, polyethylene film, or polypropylene film.

Also employed as supports may be polyester film, vinyl chloride film or nylon film, the surface of which is subjected to hydrophilic treatment. However, aluminum supports are preferably employed.

In the case of aluminum supports, employed are pure aluminum or aluminum alloys.

Various types of aluminum alloys may be employed as the supports. For example, employed may be alloys of aluminum combined with metals such as silicon, copper, manganese, magnesium, chromium, zinc, lead, bismuth, nickel, titanium, sodium, or iron. Further, employed as aluminum supports may be those which have been subjected to surface roughening to provide water retentivity.

When aluminum supports are employed, it is preferable that prior to surface roughening (being a graining treatment), supports are subjected to degreasing to remove rolling oil from the surface. Employed as degreasing are degreasing employing solvents such as TRICHLENE or thinner and emulsion degreasing employing emulsions such as triethanol. Further, employed as degreasing may be an aqueous alkali solution incorporating sodium hydroxide. By employing an aqueous alkali solution incorporating sodium hydroxide, it is possible to remove stains and oxidized layers capable of being not removed only by the above degreasing. When the aqueous alkali solution incorporating sodium hydroxide is employed for degreasing, smut is formed on the support surface. In such a case, it is preferable to perform desmut by immersing the treated support in acid such as phosphoric acid, nitric acid, sulfuric acid, chromic acid, or a mixture thereof. Listed as surface roughening methods are, for example, mechanical methods and etching methods utilizing electrolysis.

Employed mechanical surface roughening methods are not particularly limited, but a brush polishing method and a honing polishing method are preferred.

Electrochemical roughening methods are also not particularly limited, but a method is preferred in which surface roughening is electrochemically achieved in an acidic electrolyte.

After surface roughening employing the above electrochemical surface roughening method, it is preferable to immerse the resulting support in an aqueous acid or alkali solution to remove any aluminum waste particles. Employed as such acids are, for example, sulfuric acid, persulfuric acid, hydrofluoric acid, phosphoric acid, nitric acid, and hydrochloric acid, while employed as alkalis are, for example, sodium hydroxide and potassium hydroxide. Of these, it is preferable to employ the aqueous alkali solution.

The dissolved amount of aluminum on the surface is preferably 0.5-5 g/m². It is preferable that after immersing the support into the aqueous alkali solution, neutralization is affected via immersion of the resulting support into phosphoric acid, nitric acid, sulfuric acid, chromic acid, or a mixture thereof.

To achieve the desired surface roughening, a mechanical surface roughening method and an electrochemical surface roughening method may be individually employed, or surface roughening may be performed in such a manner that a mechanical surface roughening method is initially employed followed by an electrochemical one.

After the above surface roughening method, it is possible to perform an anodizing treatment. Anodizing treatments are not particularly limited and any appropriate conventional method may be employed, whereby an oxidized layer is formed on the support surface.

If desired, anodized supports may be subjected to sealing treatment. It is possible to perform such a sealing treatment employing the method known in the art such as a hot water treatment, a soda silicate treatment, an aqueous bichromate solution treatment, a nitrite treatment, or an ammonium acetate treatment.

Further, suitably employed are those which are subbed, after performing these treatments, with, for example, water-soluble resins such as polyvinylsulfonic acid, polymers and copolymers having a sulfonic acid group on the side chain, polyacrylic acid, water-soluble metal salts (such as zinc borate), yellow dyes, or amine salts. Further, preferably employed is the sol-gel treated substrate disclosed in JP-A No. 5-304358, in which a functional group, capable of inducing an addition reaction, is subjected to covalent bonding.

### (Coating)

The above photosensitive layer liquid coating composition is applied onto a support employing any appropriate method known in the art and subsequently dried, whereby it is possible to produce the targeted photosensitive planographic printing plate material.

Listed as coating methods of the liquid coating composition may, for example, be an air doctor coater method, a blade coater method, a wire bar method, a knife coater method, a dip coater method, a reverse roller coater method, a gravure coater method, a cast coating method, a curtain coater method, and an extrusion coater method.

The drying temperature of the photosensitive layer is preferably in the range of 60-160° C., is more preferably in the range of 80-140° C., but is most preferably in the range of 90-120° C.

### (Image Exposure)

In the image forming method of the present invention, employed as a light source for image exposure is a laser beam of an emission wavelength 350-450 nm.

Listed as such light sources may, for example, be a He—Cd laser (441 nm), a combination (430 nm) of Cr:LiSAF with SHG crystals as a solid laser, KNbO₃ as a semiconductor laser system), a ring resonator (430 nm), AlGaInN (350-450 nm), and AlGaInN semiconductor laser (a commercially available InGaN based 400-410 nm semiconductor laser).

Laser scanning methods include outer cylinder surface scanning, inner cylinder surface scanning, and plane scanning. In the outer cylinder surface scanning, a laser beam is exposed onto a recording material, which is wound on the exterior surface of a rotating drum. Drum rotation is referred to as primary scanning, while the movement of the laser beam is referred to as secondary scanning. In inner cylinder surface scanning, recording material is fixed on the inner surface of a drum. A laser beam is irradiated from the inner side so that primary scanning is performed in the peripheral direction by rotating a portion of, or the entire, optical system, while secondary scanning is achieved in the axial direction by linearly moving a potion of, or the entire, optical system parallel to the axis of the drum. In plane scanning, primary scanning of a laser beam is performed by combining a polygonal mirror, a galvanic mirror, and an fθ lens, while secondary scanning is performed by movement of the recording medium. Outer cylinder surface scanning and inner cylinder surface scanning are suitable for high density recording, since both of the optical accuracy are easily enhanced.

In the present invention, it is preferable that images are exposed at the plate surface energy (being the energy on the plate material) of at least 10 mJ/cm², while its upper limit is 500 mJ/cm², while the range is more preferably 10-300 mL/cm². It is possible to determine the above energy employing, for example, LASER POWER METER PDGDO-3W, produced by Ophir Optronics Co.

### (Developer)

Exposed portions of a planographic printing plate material, which has been subjected to image exposure, are hardened. By developing an image exposed planographic printing plate material, unexposed portions are removed, whereby a planographic printing plate is prepared.

Employed as such a developer may be a conventionally known aqueous alkali solution. Listed as such a developer are alkali developers which employ inorganic alkali agents such as sodium, potassium, or ammonium silicate; sodium, potassium, or ammonium secondary phosphate; sodium, potassium, or ammonium bicarbonate; sodium, potassium, or ammonium carbonate; and sodium, potassium, or ammonium borate; and sodium, potassium, ammonium, or lithium hydroxide.

Further, it is also possible to employ organic alkali agents such as monomethylamine, dimethylamine, trimethylamine, monoethylamine, diethylamine, triethylamine, mono-i-propylamine, di-i-propylamine, tri-i-propylamine, butylamine, monoethanolamine, diethanolamine, triethanolamine, mono-i-propanolamine, di-i-propanolamine, ethyleneimine, ethylenediamine, or pyridine.

These alkali agents may be employed individually or in combinations of at least two types. Further, if necessitated, incorporated in the above developer may be components such as various surface active agents, organic solvents, chelating agents, dyes, pigments, water softening agents, antiseptics, or antifoaming agents.

It is also possible to prepare an alkaline developer from developer concentrates in the form of granules or tablets.

### EXAMPLES

The present invention will now be detailed with reference to examples, however the embodiments of the present invention are not limited thereto. In these examples, “parts” are “parts by weight”, unless otherwise specified.

### Examples 1-3

### Polymer Binder: Synthesis of Acryl Based Copolymer 1

Under a nitrogen atmosphere, charged into a three-necked flask were 30 parts of methacrylic acid, 70 parts of methyl methacrylate, 500 parts of isopropyl alcohol, and 3 parts of α,α′-azobisisobutyronitrile, and the resulting mixture underwent reaction at 80° C. for 6 hours in an oil bath. Thereafter, after over one hour, refluxing was performed at a boiling point of isopropyl alcohol, 3 parts of triethylammonium chloride and 25 parts of glycidyl methacrylate were added, and the resulting mixture underwent reaction for an additional 3 hours, whereby Acryl Based Copolymer 1 was obtained. Its weight average molecular weight of about 35,000 was determined employing GCP, while its glass transition temperature (Tg) of about 105° C. was determined employing DSC (a differential thermal analysis method).

### <<Polymer Binder: Synthesis of Acryl Based Copolymer 2>>

Under a nitrogen atmosphere, charged into a three-necked flask were 18 parts of methacrylic acid, 82 parts of methyl methacrylate, 200 parts of propylene glycol, and 2.5 parts of α,α″-azobisisobutyronitrile, and the resulting mixture underwent reaction under nitrogen atmosphere at 80° C. for 6 hours in an oil bath. Thereafter, the temperature was raised to 100° C. and stirring was continued over one hour. Subsequently, the temperature was lowered to room temperature, whereby Acryl Based Copolymer 2 was obtained. Its weight average molecular weight of about 36,000 was determined employing GCP, while its glass transition temperature (Tg) of about 125° C. was determined employing DSC (a differential thermal analysis method).

### (Preparation of Support)

A 0.30 mm thick and 1,030 mm wide aluminum plate, specified in JIS A 1050 was continuously subjected to the following treatments.

(a) The above aluminum plate was subjected to a spray etching treatment at 70° C., a sodium hydroxide concentration of 2.6% by weight, and an aluminum ion concentration of 6.5% by weight, whereby the aluminum plate was dissolved by 0.3 g/m². Thereafter, washing was performed employing a water spray.
(b) A desmut treatment was performed by spraying a 1% by weight aqueous nitric acid solution (containing 0.5% by weight of aluminum ions) at 30° C., followed by washing employing water spray.
(c) An electrochemical surface roughening treatment was continuously performed employing a 60 Hz alternating current. During this treatment, the electrolyte incorporated 1.1% by weight of hydrochloric acid, 0.5% by weight of aluminum ions, and 0.5% by weight of acetic acid at a maintained temperature of 21° C. The electrochemical surface roughening treatment was performed employing a sinusoidal current, which resulted in 2 msec of TP time during which the current value reached from zero to its peak, and also employing a carbon electrode as a counter electrode. Current density was 50 A/dm² in terms of effective value, while the quantity of electricity was 9,000 C/dm². Thereafter, washing was performed employing sprayed water.
(d) A desmut treatment was performed for 10 seconds, employing a 20% by weight aqueous phosphoric acid solution (containing 0.5% by weight of aluminum ions) at 60° C., followed by washing employing a sprayed water.
(e) An anodizing treatment was performed at a sulfuric acid concentration of 170 g/l (containing 0.5% by weight of aluminum ions) in the electrolysis section at 30° C., employing an existing anodizing apparatus (the length of each of the first and second electrolysis sections being 6 m, while the length of the first and second feeding sections being 3 m, and the length of each of the first and second feeding electrodes being 2.4 m) based on a two-stage electric supply method, followed by washing employing sprayed water.

During the above treatment, in the anodizing apparatus, an electric current from the power source ran to the first feeding electrode installed in the first feeding section and further ran to an aluminum plate via the electrolyte. In the first electrolysis section, an oxidized layer was formed on the aluminum plate surface and the resulting current passed through the electrolysis electrode installed in the first feeding section, and returned to the power source.

On the other hand, an electric current from the power source ran to the second feeding electrode installed in the second feeding section, and in the same manner as above, ran to an aluminum plate via the electrolyte. In the second electrolysis section, an oxidized layer was formed on the aluminum plate surface in the second electrolysis section. The quantity of electricity fed from the power source to the first feeding section was the same as that fed from the power source to the second feeding section, and the fed current density on the oxidized layer in the second feeding section was about 35 A/dm². In the second feeding section, current was fed from the oxidized layer surface of 1.35 g/m².

The final weight of the oxidized layer was 2.7 g/m². Further, after spray washing, the resulting plate was immersed into a 0.4% by weight polyvinylsulfonic acid solution for 30 seconds, whereby a hydrophilic treatment was performed. The temperature was 75° C. Thereafter, spray washing was performed, followed by drying employing an infrared heater.

The resulting center line mean roughness (Ra) was 0.65 μm.

### (Preparation of Photosensitive Planographic Printing Plate Materials)

The photopolymerizable photosensitive layer liquid coating composition, composed as described below, was applied onto the above support, employing a wire bar to result in a dried coated weight of 1.5 g/m², and subsequently dried at 95° C. for 1.5 minutes, whereby a photopolymerizable photosensitive layer coated sample, incorporating the photosensitive composition, was prepared.

Further, the oxygen shielding layer liquid coating composition, composed as described below, was applied onto the photopolymerizable photosensitive layer coated sample, employing a wire bar to result in a dried coated weight of 1.5 g/m², and subsequently dried at 65° C. for 3 minutes, whereby Photosensitive Planographic Printing Plate Materials 1-10, incorporating the oxygen shielding layer on the photosensitive layer, were prepared.

### (Photopolymerizable Photosensitive Layer Liquid Coating Composition 1)

| | | |
|---|---|---|
| Ethylenic double bond containing monomer | 10.0 | parts |
| (NK OLIGO U-4HA, produced by Shin- | | |
| Nakamura Chemical Co., Ltd.) | | |
| Ethylenic double bond containing monomer | 5.0 | parts |
| (NK ESTER 3G, produced by Shin- | | |
| Nakamura Chemical Co., Ltd.) | | |
| Ethylenic double bond containing monomer | 38.0 | parts |
| M-6 (described in the above) | | |
| Dye listed in Table 1 | 4 | parts |
| Photopolymerization initiator listed in | 3 | parts |
| Table 1 | | |
| 2-Mercaptobenzothiazole | 0.2 | part |
| Halogen Compound 1 | 3.0 | parts |
| Copolymer at a weight average molecular | 35.0 | parts |
| weight of 35,000 of methacrylic | | |
| acid/methyl methacrylate at a | | |
| weight ratio of 18/82 | | |
| 2-t-Butyl-6-(3-t-butyl-2-hydroxy-5- | 0.5 | part |
| methylbenzyl)-4-methylphenyl | | |
| acrylate (SUMILIZER GS, produced | | |
| by Sumitomo 3M Limited) | | |
| EDAPLAN LA411 (produced by Munzing Chemie | 0.2 | part |
| GMBH) | | |
| Propylene glycol monomethyl ether | 900 | parts |

Halogen Compound 1: CBr₃CONHCH₂C(CH₃)₂CH₂NHCOCBr₃

### (Oxygen Shielding Layer Liquid Coating Composition)

| | | |
|---|---|---|
| Polyvinyl alcohol (AL-06, produced by | 94 | parts |
| Nippon Synthetic Chemical Industry | | |
| Co., Ltd.) | | |
| Polyvinylpyrrolidone (PVP K-30, produced | 5 | parts |
| by ISP Japan Co.) | | |
| Surface active agent (SURFINOL 465, | 0.5 | part |
| produced by Nissin Chemical Corp.) | | |
| Water | 900 | parts |

### (Evaluation of Planographic Printing Plate Materials)

### (Imaging Speed)

Each of the planographic printing plate materials was exposed at 2,400 dpi (dpi as described herein refers to the number of dots per 2.54 cm) employing a plate setter (NEWS CPT, produced by ECRM Co.) equipped with a 60 mW light source. of 405 nm

Employed as an exposure pattern were a 100% image portion and a 50% square dot portion. Subsequently, photographic processing was performed employing a CPT automatic processor (RAPTOR POLYMER, produced by Glunz & Jensen Co.) fitted with a pre-heating section maintained at 105° C., a pre-water washing section to remove the oxygen shielding layer, a development section loaded with the developer, composed as described below, maintained at 30° C., the water washing section to remove any developer adhered to the plate surface, and the gum solution (prepared by diluting GW-3, produced by Mitsubishi Chemical Corporation, by a factor of two) processing section.

Minimal exposure energy, which resulted in no layer decrease, was determined as recording energy, which was employed as an index of imaging speed. The lower the recording energy, the higher the imaging speed became. Table 1 shows the results.

### Developer Composition (an Aqueous Solution Incorporating the Following Additives)

| | |
|---|---|
| A potassium silicate | 8.0% by weight |
| NEWCALL B-13SN (produced by Nippon | 3.0% by weight |
| Nyukazai Co.) | |
| Potassium hydroxide | at an amount to control |
| | the pH to 12.3 |

### (Plate Life)

A planographic printing plate was prepared in such a manner that a 175-line image was exposed under 50 μJ/cm² and developed. The above plate was mounted on a printing press (DAIYA 1F-1, produced by Mitsubishi Heavy Industries, Ltd.), and printing was performed employing coated paper, a printing ink (a soybean oil ink, “NATURALIS 100”, produced by Dainippon Ink and Chemicals, Incorporated), and dampening water (H SOLUTION SG-51 at a concentration of 1.5%, produced by Tokyo Ink Mfg. Co., Ltd.). The number of the printed sheet, which resulted in noticeable dot loss in the highlight portions, was employed as an index of plate life. Table 1B shows the results.

(Sensitivity Change after Storage at High Temperature)

Each of the planographic printing plate materials thus prepared was put in a black colored polyethylene envelop which prevents transmission of light, and then it was left in a thermostatic chamber at 55° C. for 3 days.

After subjected to the above-described condition, the imaging speed of each of the materials was measured in the same way as applied for the planographic printing plate materials without subjected to high temperature storage as described above. The inventive samples exhibited small change of imaging speed in contrast to comparative samples. The results are shown in Table 1B.

TABLE 1B

| Photo- | | | | | | |
|---|---|---|---|---|---|---|
| sensi- | | | | | | Imaging |
| tive | | | | | Imaging | Speed |
| Plano | | | Photo- | | Plate | (μJ/cm²) |
| graphic | | | poly- | | Life | after |
| Printing | | | merri- | Imaging | (as | Storage |
| Plate | Re- | | zation | Speed | number of | at High |
| Material | marks | Dye | Initiator | (μJ/cm²) | sheets) | Temperature |
| 1 | Inv. | D-9 | I-1 | 10 | at least | 15 |
| | | | | | 200,000 | |
| 2 | Comp. | D-10 | I-1 | 15 | 150,000 | 80 |
| 3 | Inv. | D-17 | I-1 | 10 | at least | 15 |
| | | | | | 200,000 | |
| 4 | Inv. | D-9 | I-2 | 30 | 150,000 | 30 |
| 5 | Comp. | D-10 | I-2 | 20 | at least | 100 |
| | | | | | 200,000 | |
| 6 | Inv. | D-17 | I-2 | 20 | at least | 20 |
| | | | | | 200,000 | |
| 7 | Comp. | DR-1 | I-1 | 150 | 80,000 | Un- |
| | | | | | | measurable |
| 8 | Comp. | DR-1 | I-2 | 130 | 50,000 | 150 |
| 9 | Comp. | DR-2 | I-1 | 150 | 50,000 | Un- |
| | | | | | | measurable |
| 10 | Comp. | DR-3 | I-1 | 180 | 30,000 | Un- |
| | | | | | | measurable |
| 11 | Comp. | D-13 | I-1 | 20 | 100,000 | 80 |
| 12 | Comp. | D-13 | I-2 | 35 | 100,000 | 120 |

Inv.: Present Invention,
Comp.: Comparative Example
I-1: 2,2′-bis(2-chlorophenyl)-4,5,4′,5′-tetraphenylbiimidazole
I-2: η-cumene-(η-cyclopentadienyl)iron hexafluorophosphate
DR-1: 4-methyl-7-diethylaminocoumarin
DR-2: 3-methoxycarbonyl-7-diethylaminocoumarin
DR-3: 3-styrylcarbonyl-7-diethylaminocoumarin
D-10:

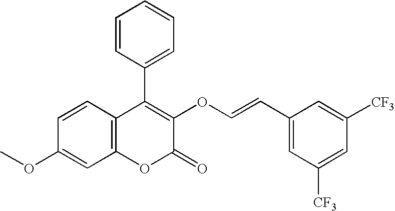

D-13:

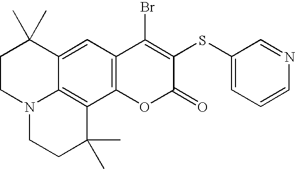

As can be seen from Table 1, the photosensitive planographic printing plate materials of the present invention resulted in higher imaging speed and longer plate life. The printing plate materials of the present invention exhibited small change of Imaging speed even after stored at high temperature. The description of “unmeasurable” indicates that the Imaging speed is too low to be measured (too large number).

What is claimed is:

1. A photosensitive composition comprising:
(A) a polymerizable compound containing an ethylenic double bond in the molecule;
(B) a photopolymerization initiator;
(C) a polymer binder; and
(D) a dye exhibiting a maximum absorption wavelength of 350-450 nm,
wherein the dye is represented by Formula (1): 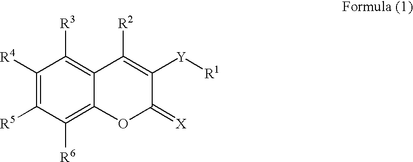
wherein R¹ represents an aryl group which may have a substituent, a heterocyclic group which may have a substituent, or —CH═CH—R¹¹, provided that R¹¹ represents an alkenyl group which may have a substituent, or an aryl group which may have a substituent, R² and R³ each independently represents a hydrogen atom, a halogen atom, a cyano group, an alkyl group, an aryl group, or an acyl group, each of which may have a substituent; R⁴ and R⁶ each independently represents a hydrogen atom or an alkyl group which may have a substituent; R⁵ represents —NR⁷R⁸ or —OR⁹, provided that R⁷ and R⁸ each independently represents a hydrogen atom, an alkyl group, or an aryl group, each of which may have a substituent; and R⁷ and R⁴, and R⁸ and R⁶ may be joined to form a 5- to 6-membered ring; R⁹ represents an alkyl group or an aryl group, each of which may have a substituent; X represents an oxygen atom or a sulfur atom; and Y represents —CR¹⁰R¹¹, provided that R¹⁰ and R¹¹ each independently represents a hydrogen atom or an alkyl group.

2. The photosensitive composition of claim 1,
wherein R⁵ in Formula (1) is —NR⁷R⁸.

3. The photosensitive composition of claim 1,
wherein (B) the photopolymerization initiator is an iron arene complex.

4. The photosensitive composition described in claim 1,
wherein (B) the photopolymerization initiator is a biimidazole compound.

5. A photosensitive planographic printing plate material comprising a support having thereon a photosensitive layer composing the photosensitive composition of claim 1.

6. An image forming method of a photosensitive planographic printing plate material comprising the step of:
imagewise exposing the photosensitive planographic printing plate material of claim 5 to a laser beam having a emission wavelength of 350-450 nm.
